(19) United States
(12) Patent Application Publication
(10) Pub. No.: US 2009/0137083 A1
(43) Pub. Date: May 28, 2009

(54) ASSEMBLING OF DOUBLED-SIDE STACKING PULRAL CHIPS

(75) Inventor: Chin-Ti Chen, Hukou Shiang (TW)

Correspondence Address: Muncy, Geissler, Olds & Lowe, PLLC, P.O. BOX 1364, FAIRFAX, VA, 22038-1364, US

(73) Assignee: POWERTECH TECHNOLOGY INC.

(21) Appl. No.: 12/138,938

(22) Filed: Jun. 13, 2008

(30) Foreign Application Priority Data
Nov. 22, 2007 (TW) 096144359

(51) Int. Cl. H01L 21/00

(52) U.S. Cl. 438/107; 257/E21.499

(57) ABSTRACT

Disclosed is a method for assembling a semiconductor device, especially to dispose a plurality of chips on double sides of a chip carrier, such as a lead frame. At least a first chip is disposed on one surface of the chip carrier. Then, a protecting spacer is disposed on the active surface of the first chip. Then, the chip carrier is flipped over and placed on a hot plate where the protecting spacer keeps the active surface of the first chip away from direct contact with the hot plate. After the flipping and placing step, at least a second chip is disposed on another surface of the chip carrier and then is electrically connected to the chip carrier by a plurality of bonding wires. Therefore, any damages to the active surface of the first chip are avoided during disposition and electrical connections of the second chip.

### FIELD OF THE INVENTION

The present invention relates to an assembling technology of semiconductor devices, especially to a method of stacking multiple chips on double sides of a chip carrier, such as lead frame.

### BACKGROUND OF THE INVENTION

As semiconductor devices for the electronic products such as computers and hand-held communications become smaller with more functions, more chips need to be accommodated within a limited space. In order to fully utilize the limited space in the semiconductor devices, two or more chips are disposed on the top surface and on the bottom surface of a chip carrier, such as a lead frame.

Conventional double-side stacking technology of multiple chips is shown in FIG. 1, at least a first chip 120 is disposed on the first surface 111 of a chip carrier 110 such as a lead frame where the active surface 121 of the first chip 120 is disposed away from the first surface 111. A plurality of first bonding pads 122 are formed on the active surface 121 of the first chip 120 where the first bonding pads 122 are electrically connected to a plurality of leads 113 of the chip carrier 110 by a plurality of first bonding wires 141. When stacking a plurality of the first chips 120, a first interposer 151 is disposed between the first chips 120 to provide wire-accommodating spacing between the first chips 120. Then, the chip carrier 110 is flipped over, at least a second chip 130 is disposed on the second surface 112 of the chip carrier 110 where the second chip 130 has a plurality of second bonding pads 131 and is electrically connected to the chip carrier 110 by a plurality of second bonding wires 142. When stacking the plurality of second chips 130, a second interposer 152 is disposed between the second chips 130 to provide a proper space to avoid the second bonding wires 142 being in contact with the backside of the upper second chip 130.

Before disposing the second chip 130, the chip carrier 110 with disposed the first chips 120 is flipped over and is placed on a hot plate 10 so that the second surface 112 of the chip carrier 110 will face upward. The leads 113 of the chip carrier 110 are fixed on the hot plate 10 by a clamp 20. As shown in FIG. 1 again, the active surface 121 of the first chip 120 is faced downward and is in directly contact with a stage of the hot plate 10 after flipping the chip carrier 110 over. Then the second chip 130 is disposed on the chip carrier 10 and is wire bonded where a die-attaching force and wire bonding forces will exert on the second chip 130. These forces will damage the first active surface 121 of the first chip 120. Moreover, since the material of the first chip 120 is brittle, excess stresses will cause the first chip 120 to crack.

### SUMMARY OF THE INVENTION

The main purpose of the present invention is to provide a method for assembling a semiconductor device without chip damages to effectively prevent any damages or cracks to the bottom chips after flipping over to achieve higher package quality and higher packaging yield.

According to the present invention, a method for assembling a semiconductor device primarily comprises the following steps. Firstly, a chip carrier is provided, where the chip carrier has a first surface and a second surface. Then, at least a first chip is disposed on the first surface of the chip carrier, where a plurality of first bonding pads are formed on the active surface of the first chip with the active surface away from the first surface of the chip carrier. Then, the first bonding pads of the first chip are electrically connected to the chip carrier by a plurality of bonding wires. After the first electrical connections, a protecting spacer is disposed on the active surface of the first chip. Then, the chip carrier is flipped over and is then placed the chip carrier on a hot plate, where the protecting spacer keeps the active surface of the first chip away from direct contact with the hot plate. Then, at least a second chip is disposed on the second surface of the chip carrier, where a plurality of second bonding pads are formed on the active surface of the second chip with the active surface away from the second surface. Finally, the second bonding pads of the second chip are electrically connected to the chip carrier.

### DESCRIPTION OF THE DRAWINGS

FIG. 1 shows a cross-sectional view of a stacked-chip assembly by a conventional double-side stacking technology of multiple chips after flipping a chip carrier over.

FIG. 2 shows the process flow of a method for assembling a semiconductor device according to the present invention.

FIGS. 3A to 3H show the cross-sectional views of a chip carrier during the double-side chip stacking processes according to the first embodiment of the present invention.

FIG. 4 shows a cross-sectional view of a stacked-chip assembly after flipping a chip carrier over according to the second embodiment of the present invention.

FIG. 5 shows the top view of a first chip of the stacked-chip assembly with a protecting spacer according to the second embodiment of the present invention.

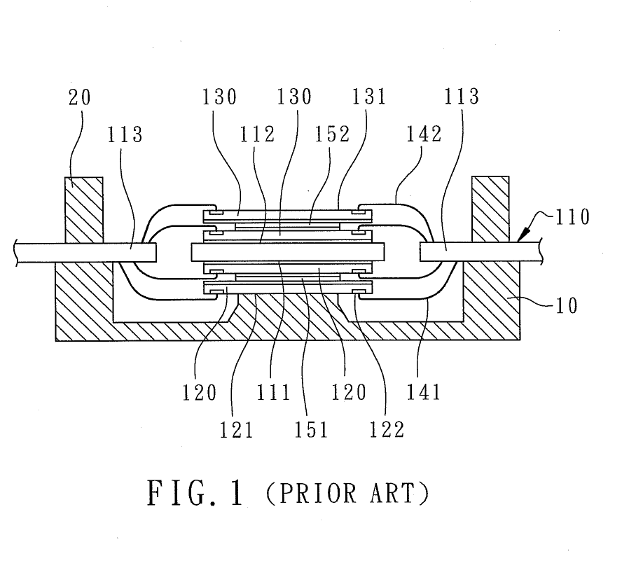

### DETAIL DESCRIPTION OF THE INVENTION

Please refer to the attached drawings, the present invention will be described by means of embodiments below.

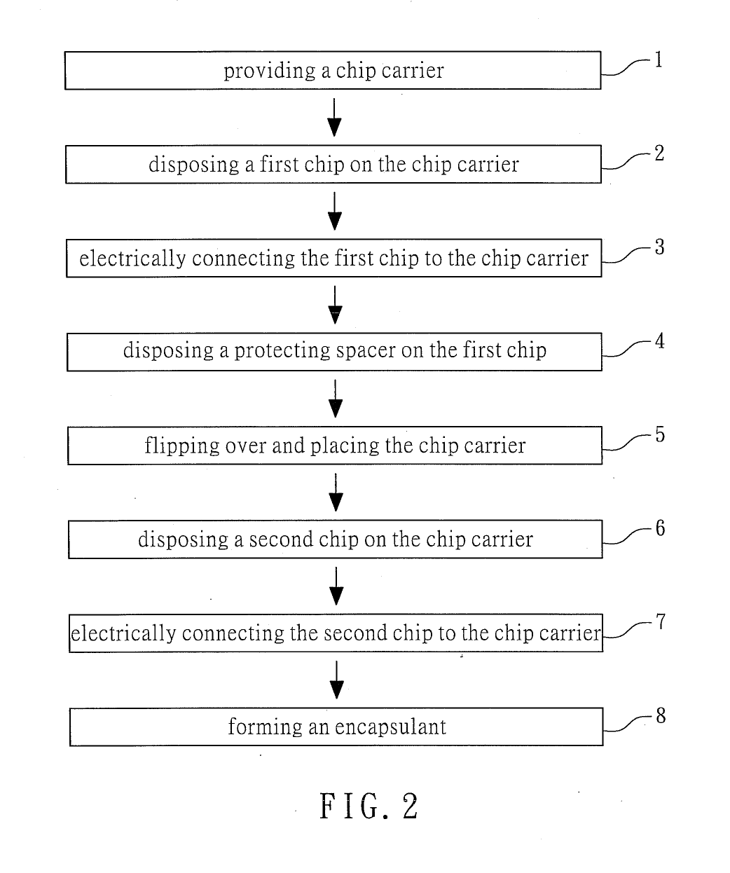

As shown in FIG. 2, a method for assembling a semiconductor device primarily comprises the following processing steps of: step 1 of “providing a chip carrier”, step 2 of “disposing a first chip on the chip carrier”, step 3 of “electrically connecting the first chip to the chip carrier”, step 4 of “disposing a protecting spacer”, step 5 of “flipping over and placing the chip carrier”, step 6 of “disposing a second chip on the chip carrier”, step 7 of “electrically connecting the second chip to the chip carrier”, and step 8 of “forming an encapsulant”.

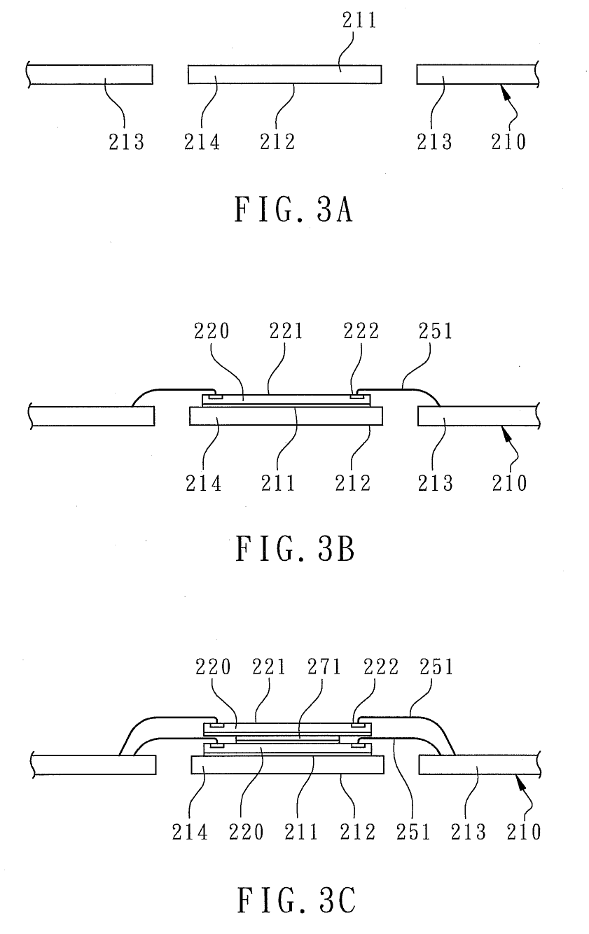

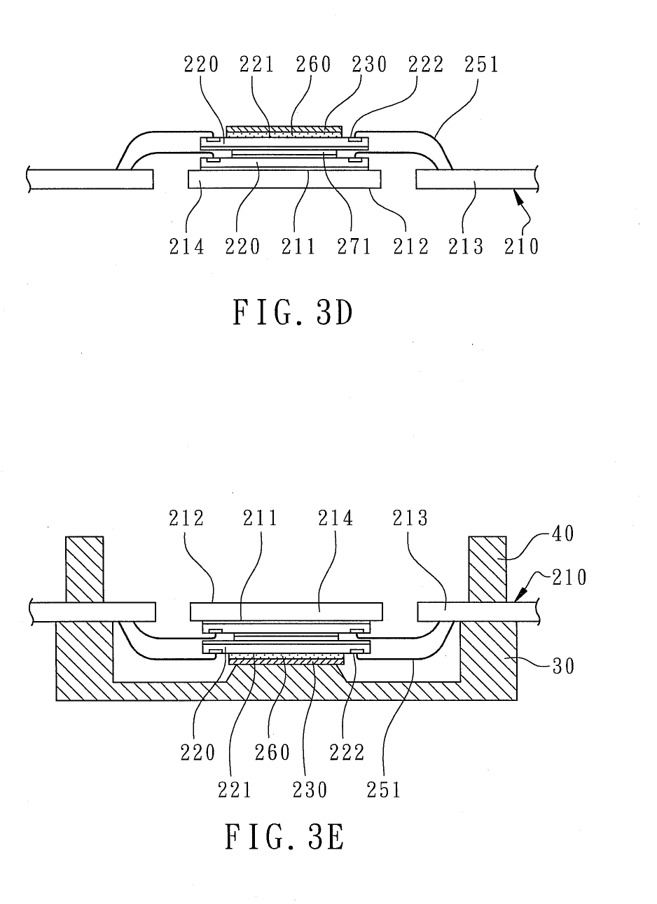

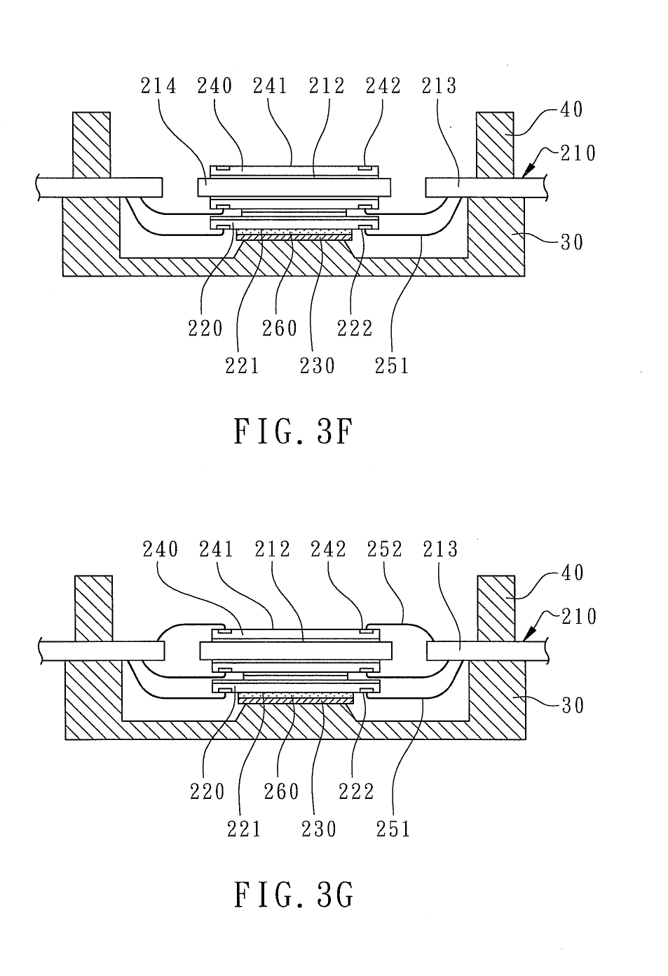

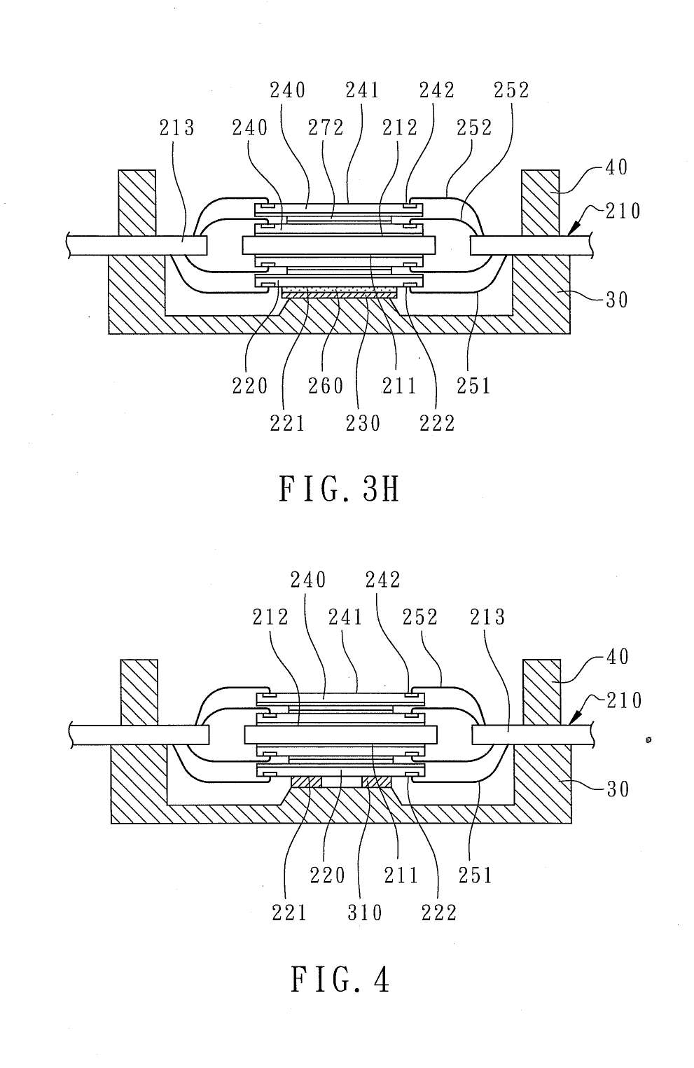

As shown in FIGS. 3A to 3H, the assembling process flow is described in detail as follows. Firstly, step 1 of “providing a chip carrier” is performed as shown in FIG. 3A. A chip carrier 210 has a first surface 211 and a second surface 212. In the present embodiment, the chip carrier 210 can be a lead frame including a plurality of leads 213 where the chip carrier 210 further includes a die pad 214 of the lead frame for double-side disposing multiple chips.

Then, step 2 of “disposing the first chip on a chip carrier” can be shown in FIG. 3B. At least a first chip 220 is disposed on the first surface 211 of the chip carrier 210 where a plurality of bonding pads 222 are formed on a first active surface 221 of the chip 220 with the first active surface 221 facing away from the first surface 211. The bonding pads 222 are arranged on the sides of the first active surface 221 such as on two corresponding sides or on the peripheries.

Then, step 3 of “electrically connecting the first chip to the chip carrier” is performed as shown in FIG. 3B again. A plurality of bonding wires 251 are formed by wire bonding and electrically connecting the first bonding pads 222 of the first chip 220 to the leads 213 of the chip carrier 210 so that the first chip 220 is electrically connected with the chip carrier 210.

As shown in FIG. 3C, in the present embodiment, another first chip 220 is stacked on top of a lower first chip 220 with the first active surface 221 faced upward. A plurality of the first bonding wires 251 electrically connect the first bonding pads 222 of the upper first chip 220 to the leads 213 of the chip carrier 210 where a first interposer 271 is disposed between the stacked first chips 220 to provide wire-accommodating space and to avoid backside of the upper first chip 220 directly contact with the first bonding wires 251.

Step 4 of “disposing a protecting spacer on the first chip is performed as shown in FIG. 3D. A protecting spacer 230 is disposed on the first active surface 221 of the upper first chip 220 to keep the first active surface 221 of the first chip 220 from damages in the following stacking process flow. The protecting spacer 230 is disposed at the center of the first active surface 221 of the first chip 220. In the present embodiment, the protecting spacer 230 is a rectangle or a square without covering the first bonding pads 222. Moreover, in the present embodiment, the protecting spacer 230 is brittle prone to easily break such as silicon spacer, dummy chip or other brittle material. The protecting spacer 230 is more brittle than the first chip 220. During the following stacking process flow, cracks are acceptable in the protecting spacer 230. Normally, the thickness of the protecting spacer 230 is smaller than the one of the first chip 220. Preferably, the thickness of the protecting spacer 230 is larger than the loop height of the first bonding wires 251 during the first electrical connection step. Accordingly, the height of the stage at the center of the hot plate 30 can be reduced and the first bonding wires 251 will not directly contact with the hot plate 30 (as shown in FIG. 3E). As shown in FIG. 3D, preferably, a stress-buffering layer 260 is disposed between the protecting spacer 230 and the first chip 220 to provide a stress-buffering function to reduce the damages of the first chip 220. The protecting spacer 230 has heat conductivity not less than the one of the first chip 220 to enhance heat dissipation of the stacked semiconductor package.

Then, step 5 of “flipping over and placing the chip carrier” is performed as shown in FIG. 3E. The chip carrier 210 with the disposed first chip 220 is flipped over and then is placed on a hot plate 30 so that the second surface 212 of the chip carrier 210 is faced upward for disposing the second chip 240. The protecting spacer 230 keeps the first active surface 221 of the first chip 220 away from direct contact with the central stage of the hot plate 30. The leads 213 are fixed on the hot plate 30 by a clamp 40. In the present embodiment, the hot plate 30 has a W-shaped cross section. Additionally, the protecting spacer 230 also protects the first bonding wires 251 without contacting with the hot plate 30 so that the height of the central stage of the hot plate 30 can be reduced. The hot plate 30 is to possibly have a U-shaped cross-section depending on the thickness of the protecting spacer 230.

Then, step 6 of “disposing a second chip on the chip carrier” is performed as shown in FIG. 3F. At least a second chip 240 has a plurality of bonding pads 242 and is disposed on the second surface 212 of the chip carrier 210 with the second active surface 241 of the second chip 240 facing away from the second surface 212. In this embodiment, the first chip 220 and the second chip 240 are disposed on the first surface 211 and on the second surface 212 of the die pad 214 of a lead frame. Therefore, during die attachment of the second chip 240, the die-attaching force exerted on the second chip 240 will pass through the first chip 220, the protecting spacer 230 and to the hot plate 30. Any stresses due to uneven die attachment will exert on the protecting spacer 230. Even if the protecting spacer 230 is cracked, the ICs on the first active surface 221 of the first chip 220 are protected without any damages.

Step 7 of “electrically connecting the second chip to the chip carrier” is shown in FIG. 3G. The second bonding pads 242 of the second chip 240 are electrically connected to the leads 213 of the chip carrier 210 by a plurality of second bonding wires 252. During the second electrical connections, the wire-bonding forces to form the second bonding wires 252 will also pass through the first chip 220, the protecting spacer 230 to the hot plate 30. The ICs on the first active surface 221 of the first chip 220 are protected by the protecting spacer 230 to be free from damages.

During step 6, a die-attaching force is exerted downward at the center of the second chip 240 to attach the second chip 240 on the second surface 212 of the chip carrier 210. During step 7, the wire-bonding forces are also exerted downward at the peripheries of the second active surface 241 of the second chip 240 in order to electrically connect one end of the second bonding wires 252 to the second bonding pads 242. To be more specific, downward forces in step 6 and step 7 will exert at different locations of the second chip 240. Since the protecting spacer 230 is disposed on the first active surface 221 of the first chip 220 and is directly contacted with the hot plate 30, the downward forces exerted on the second chip 240 will pass to the protecting spacer 230 first to cause any possible cracks in the protecting spacer 230, i.e., when experiencing stresses, the protecting spacer 230 will crack earlier than the first chip 220 to achieve the protection of the first chip 220 and to enhance the stacking yield. Furthermore, preferably, a stress-buffering layer 260 is disposed between the protecting spacer 230 and the first chip 220 as a stress buffer to further protect the first active surface 221 of the first chip 220 and to avoid damages or cracks of the first chip 220. Therefore, the protecting spacer 230 will absorb the die-attaching force from attaching of the second chip 240 in step 6 and the wire-bonding forces from the second electrical connections in step 7 to effectively prevent any cracks of the first chip 220 or any damages at the first active surface 221 to achieve higher package quality and higher stacking yield.

As shown in FIG. 3H, in the present embodiment, another second chip 240 can be stacked on top of the lower second chip 240 with the second active surface 241 faced upward. A plurality of the second bonding wires 252 are electrically connected the second bonding pads 242 of the upper second chip 240 to the leads 213 of the chip carrier 210 where a second interposer 272 is disposed between the second chips 240 stacked on top and at the bottom to provide wire-accommodating space and to avoid the second chip 240 on top to directly contact with the second bonding wires 252.

The method mentioned above further comprises the step 8 of “forming an encapsulant”. An encapsulant is formed to encapsulate the first chip 220, the second chip 240, the first bonding wires 251, the second bonding wires 252 and the die pad 214 by transfer molding or by printing. The encapsulant may further encapsulate the protecting spacer 230, not shown in the figure. Accordingly, the chips 220 and 240 and the bonding wires 251 and 252 are free from contaminations.

As shown in FIG. 3H again, a semiconductor device assembled by the method according to the present invention, primarily comprises the chip carrier 210, the first chip 220, the protecting spacer 230, and the second chip 240. The first chip 220 is disposed on the first surface 211 of the chip carrier 210 and the protecting spacer 230 is disposed on the first active surface 221 of the first chip 220 to protect the first chip 220. The second chip 240 is disposed on the second surface 212 of the chip carrier 210. The first chip 220 and the second chip 240 are electrically connected to the chip carrier 210 by a plurality of the bonding wires 251 and 252. To be more specific, the semiconductor device further comprises an encapsulant, not shown in the figure, encapsulates the first chip 220, the second chip 240, the die pad 214, and the protecting spacer 230.

Therefore, the semiconductor device according to the present invention can effectively avoid damages of the first chip during second die attaching and second wire bonding processing steps after flipping the chip carrier 210 over. Moreover, the protecting spacer 230 disposed on the first active surface 221 of the first chip 220 can effectively avoid direct contacts the first active surface 221 of the first chip 220 to the hot plate 30, as shown in FIG. 3H. Furthermore, the protecting spacer 230 can effectively absorb the stresses for the first chip 220 to avoid any cracks or damages on the first chip 220.

In the second embodiment of the present invention, another method for assembling a semiconductor device is revealed where most of the processing steps and the package structure is approximately the same as the first embodiment, including from step 1 to step 8 as shown in FIG. 2. As shown in FIG. 4, the semiconductor device manufactured from the method, primarily comprises a chip carrier 210, at least a first chip 220, a protecting spacer 310, and at least a second chip 240. The rest of the components will follow the numbers of the first embodiment.

The first chip 220 is disposed on the first surface 211 of the chip carrier 210 and is electrically connected to the leads 213 of the chip carrier 210 by a plurality of first bonding wires 251. After flipping the chip carrier 210 over, the second chip 240 is disposed on the second surface 212 of the chip carrier 210 and is electrically connected to the leads 213 of the chip carrier 210 by a plurality of second bonding wires 252.

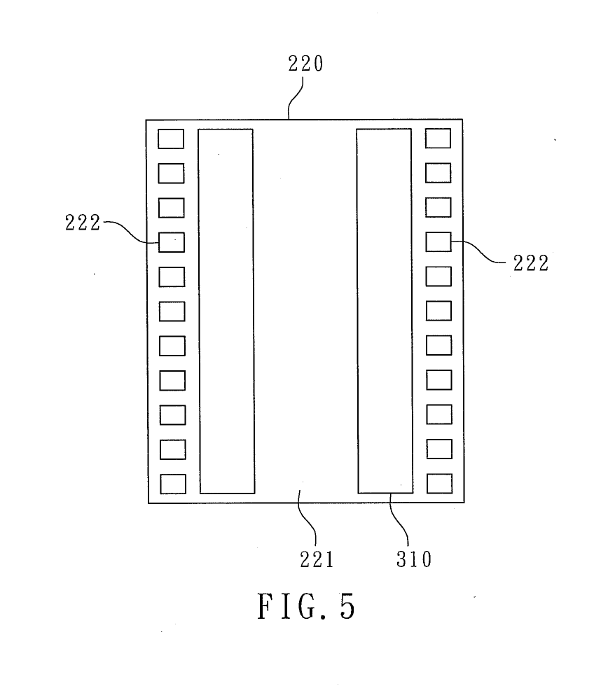

As shown in FIG. 4, before flipping the chip carrier 210 over, a protecting spacer 310 is disposed on the first active surface 211 of the first chip 220. After flipping, the chip carrier 210 is placed on a hot plate 30, the first chip 220 will not directly contact with the hot plate 30 due to the protecting spacer 310. The shape of the protecting spacer 310 is not limited according the present invention. As shown in FIG. 5, the protecting spacer 310 is formed as a plurality of strips where the strips of the protecting spacer 310 are parallel to each other and adjacent to the first bonding pads 222 to support wire bonding and to maintain the mold flow balance on the top and on the bottom of the chip carrier 210 during step 8 of “forming an encapsulant”.

Accordingly, the method according to the present invention can effectively avoid damages to the first active surface 221 of the first chip 220 due to second die attaching of the second chip 240 (step 6) and second wire bonding step (step 7) after flipping the chip carrier over (step 5) to achieve higher package quality and higher stacking yield.

The above description of embodiments of this invention is intended to be illustrative and not limiting. Other embodiments of this invention will be obvious to those skilled in the art in view of the above disclosure.

What is claimed is:

1. A method for assembling a semiconductor device, primarily comprising the steps of:
providing a chip carrier having a first surface and a second surface;
disposing at least a first chip on the first surface, wherein the first chip has a first active surface away from the chip carrier and a plurality of first bonding pads on the first active surface;
electrically connecting the first bonding pads to the chip carrier;
disposing a protecting spacer on the active surface of the first chip;
flipping the chip carrier over and then placing the chip carrier on a hot plate, wherein the protecting spacer keeps the active surface of the first chip away from direct contact with the hot plate;
disposing at least a second chip on the second surface, wherein the second chip has a second active surface away from the chip carrier and a plurality of second bonding pads on the second active surface; and
electrically connecting the second bonding pads to the chip carrier.

2. The method as claimed in claim 1, wherein the heat conductivity of the protecting spacer is not smaller than the one of the first chip.

3. The method as claimed in claim 2, wherein the protecting spacer is a silicon spacer.

4. The method as claimed in claim 1, wherein the protecting spacer does not cover the first bonding pads.

5. The method as claimed in claim 1, wherein the protecting spacer is formed as a plurality of strips.

6. The method as claimed in claim 5, wherein the strips of the protecting spacer are parallel to each other and adjacent to the first bonding pads.

7. The method as claimed in claim 1, wherein a plurality of first bonding wires are formed to electrically connect the first chip to the chip carrier during the first electrically connecting step, wherein the thickness of the protecting spacer is greater than the loop height of the first bonding wires.

8. The method as claimed in claim 7, wherein a plurality of second bonding wires are formed to electrically connect the first chip to the chip carrier during the second electrically connecting step.

9. The method as claimed in claim 1, further comprising the step of forming an encapsulant to encapsulate the first chip and the second chip.

10. The method as claimed in claim 1, wherein the chip carrier is a lead frame including a plurality of leads.

11. The method as claimed in claim 10, wherein the lead frame further includes a die pad for disposing the first chip and the second chip.

12. The method as claimed in claim 10, wherein a clamp is pressed on the hot plate to fix the leads during the flipping and placing step.

13. The method as claimed in claim 1, wherein the heat plate has a W-shaped cross-section.

14. The method as claimed in claim 1, wherein the heat plate has a U-shaped cross-section.

15. The method as claimed in claim 1, wherein the protecting spacer is made of brittle material.

16. The method as claimed in claim 15, wherein there are cracks formed in the protecting spacer.

17. The method as claimed in claim 1, wherein a stress-buffering layer is formed between the first chip and the protecting spacer.
